(19) United States
(12) Patent Application Publication
(10) Pub. No.: US 2008/0290952 A1
(43) Pub. Date: Nov. 27, 2008

(54) Dvd Reading Apparatus

(75) Inventor: Holger Pless, Erfurt (DE)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Mekexis NV, Leper (BE)

(21) Appl. No.: 11/629,608

(22) PCT Filed: Jun. 20, 2005
(86) PCT No.: PCT/IB05/01734

§ 371 Date: May 5, 2008

(30) Foreign Application Priority Data
Jun. 18, 2004 (GB) 0413610.7

(51) Int. Cl. H03F 3/08

(52) U.S. Cl. 330/308

(57) ABSTRACT

A photodiode (201) is positioned so as to detect a beam of light reflected from the surface of a spinning DVD. In response to the detection of incident light, the photodiode (201) generates a signal, which is input to a trans-impedance amplifier (203). The output of the trans-impedance amplifier (203) is input to a voltage amplifier (204), to generate an output signal for processing. The trans-impedance amplifier (203) is provided with a feedback arrangement comprising a resister (205) in parallel with a capacitor (206) and a diode (207), in this case embodied by a transistor (such as an MOS transistor) arranged to act as a diode. At an input voltage wherein the corresponding output voltage is equal to the maximum normal operating voltage, diode (207) begins to conduct and capacitor (206) becomes operative. As a result, the feedback conditions change, reducing the effective gain of the trans-impedance amplifier (203). As a result, outside of the normal operating ranges, the output voltage increases more slowly for a given increase in input voltage than in the normal operating range, thus a much larger input voltage can be tolerated without saturating the trans-impedance amplifier (203).

The invention relates to reading data from a DVD and more particularly to apparatus for reading data from a DVD.

On a DVD, data is encoded in a spiral track on the DVD surface. DVD reading apparatus operates by directing a narrow beam of light, typically generated by an LED, VCSEL, or laser diode, at the spiral track of a spinning DVD. Sections of the track have varying reflective properties, such that a light sensing means provided in a particular position will detect a series of variations (or pulses) in the intensity of the reflected light. The light sensing means thus generates an electrical output signal corresponding to the data stored on the DVD. In order that the output of the light sensing means is suitable for input to any external device, it is passed through amplification and processing means to generate a true output data stream.

In known DVD readers, the light beam is in the blue, red or near infrared region of the spectrum having typical wavelengths of approximately 405 nm, 650 nm, 780 nm or similar respectively. The detector is a photodiode connected to ground or other supply voltage, operative to generate an output signal in response to incident light. The output signal is connected to an input of a voltage amplifier via a trans-impedance amplifier. The voltage amplifier generates a signal for input to processing circuitry. Typically, such DVD readers comprise four or more photodiodes and associated amplification and processing circuitry, in order to improve the performance of the reader. In such cases, typically the output of the trans-impedance amplifier associated with each photodiode is fed to a multi-input summing amplifier, in addition to being fed to the associated voltage amplifier. The summing amplifier sums the signals from each trans-impedance amplifier, in order to generate a clock signal.

To increase the read rate of such DVD readers, the DVD is spun at a faster rate. This allows light to be reflected from a greater length of the data track in a given time period. In order that neighbouring bits of data can be distinguished clearly, it is however necessary to increase the intensity of the light beam. However, if the read rate is increased, eventually the increased intensity of the light beam means that the intensity of the reflected light is sufficiently high that the photodiode or the associated amplifier system saturates. The recovery time from a saturated state can be extremely long compared with the normal switching time and thus provides a serious or catastrophic limitation to DVD reader performance.

It is therefore an object of the present invention to provide an amplification arrangement suitable for use in a DVD reader that overcomes or alleviates the above problem.

According to the present invention there is provided an amplification arrangement, suitable for use in a DVD reading apparatus, comprising: a trans-impedance amplifier adapted to receive an input signal and to provide an output signal; a feedback resistor connected in parallel with the trans-impedance amplifier; and a moderating arrangement connected in parallel with said feedback resistor and said trans-impedance amplifier wherein said moderating arrangement is operable to moderate the gain of the trans-impedance amplifier if the output signal of the trans-impedance amplifier exceeds a predetermined level.

This arrangement thus provides a low cost amplification arrangement for use in DVD readers that reduces the likelihood of saturation and thus improves the performance of such DVD readers in terms of read speed and reliability.

Preferably, said moderating arrangement comprises a diode. Preferably, the diode is adapted such when the output voltage of the trans-impedance amplifier is greater than a predetermined level, a current will flow through the diode, thus altering the feedback characteristics such that the effective gain of the trans-impedance amplifier is reduced.

Preferably, the diode may be connected in parallel with additional feedback components as other circuit requirements may demand. Such components are indicated in the drawings by a capacitor. In one preferred embodiment, the additional feedback components comprise a capacitor arranged in parallel with a resistance. In some embodiments, the diode can be replaced with a transistor adapted to act as a diode.

Preferably, the amplification arrangement further incorporates a diode clamp, said diode clamp comprising a diode connected between a reference voltage and the trans-impedance amplifier, said diode clamp being operable to limit the magnitude of the output of the trans-impedance amplifier.

Preferably, the amplification arrangement further comprises a voltage amplifier connected to the output of the trans-impedance amplifier.

Preferably, the input signal is generated by a photodiode. A current mirror may be provided between said photodiode and said amplification arrangement, one output of the current mirror being input into the trans-impedance amplifier. In such embodiments, the photodiode is preferably connected between a positive supply rail and the current mirror. The photodiode may alternatively be connected to ground, if desired.

Preferably, the amplification arrangement is implemented in an integrated circuit such a CMOS integrated circuit or a BiCMOS integrated circuit. Most preferably said photodiode and or said current mirror are implemented as part of the same integrated circuit as said amplification arrangement.

According to a second aspect of the present invention there is provided a DVD reading apparatus comprising: a plurality of photodiodes; a plurality of amplification arrangements each, amplification arrangement associated with one of the plurality of photodiodes; and processing circuitry wherein the output of each photodiode is connected to an amplification arrangement according to the first aspect of the present invention and the output of the amplification arrangement is connected to the processing circuitry.

Preferably such a DVD reading apparatus additionally comprises means for generating and directing a beam of light at any desired point on the surface of a DVD and means for retaining and rotating a DVD. Preferably, the plurality of photodiodes are mounted in such a manner that light reflected from said desired point on the DVD surface is incident upon the photodiodes. The light generating means may be adapted to generate light of any suitable wavelength or wavelength range, including but not limited to: blue, in particular 405 nm or similar; red, in particular 650 nm or similar; or near infrared, in particular 780 nm or similar. The photodiodes may be adapted to detect only light of the same wavelength as that reflected from the DVD, by means of a filter or otherwise.

Preferably, the plurality of photodiodes comprises four or eight photodiodes. Most preferably, the outputs of the amplification arrangements associated with each photodiode are input to the processing circuitry individually. Additionally, said output of each amplification arrangement may be fed to separate input of a multi-input summing amplifier to generate a combined output signal. Said combined output signal may be used as a clock signal.

In said second aspect of the present invention, said amplification arrangement may incorporate any or all features disclosed in respect of the first aspect of the present application.

It is of course envisaged that this invention may be adapted to be used to read data from other optical storage media, if desired.

In order that the invention is more clearly understood, it will now be described further herein, by way of example only and with reference to the following drawings in which:

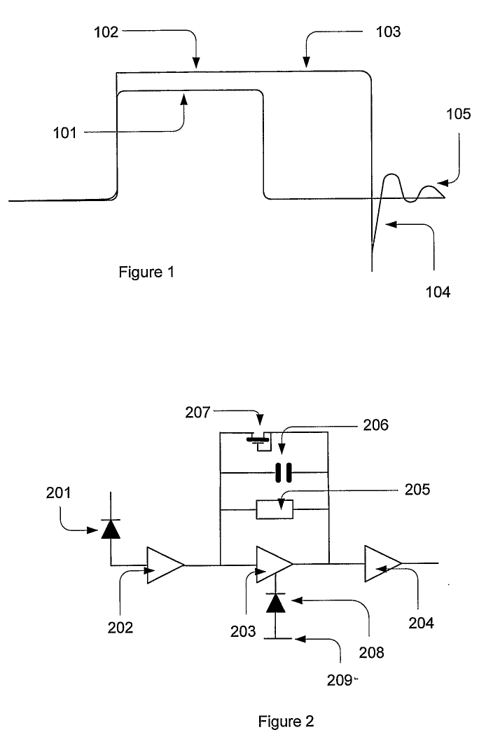

FIG. 1 illustrates a typical saturated and non-saturated response to a light pulse by a known amplification arrangement;

FIG. 2 shows a schematic diagram of one embodiment of an amplification arrangement according to the present invention; and

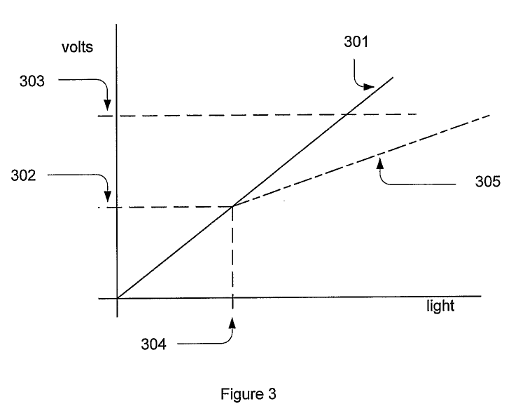

FIG. 3 shows a plot of the output of the amplification arrangement (Y-axis) against input from a photodiode (X-axis), illustrating the effect of the moderating arrangement provided in the present invention.

In a DVD reading apparatus, light is reflected from the surface of a DVD and detected by a photodiode as is described above. The output of the photodiode is fed to an amplification arrangement, typically comprising a trans-impedance amplifier and a voltage amplifier, the trans-impedance amplifier receiving the output of the photodiode and generating a corresponding signal for input to the voltage amplifier. If the output of the photodiode exceeds a maximum level, the trans-impedance amplifier arrangement will go into saturation and the signal output by the trans-impedance amplifier will not correspond to the output of the photodiode.

Referring now to FIG. 1, two contrasting outputs 101, 102 of the trans-impedance amplifier in response to the detection of a pulse of light of duration T by the photodiode are shown. In the case of output 101, the photodiode generates an electrical pulse of duration T in response to the pulse of light, the electrical pulse then being input to the trans-impedance amplifier. This subsequently results in the trans-impedance amplifier generating output pulse 101 of duration T and having a level less than the saturation level of the trans-impedance amplifier. In the second case, the light pulse is again of duration T but the intensity of the detected light is slightly higher than in the previous example. The photodiode again generates an electrical pulse of duration T in response to the pulse of light, the electrical pulse then being input to the trans-impedance amplifier. The electrical pulse is of a slightly higher level than in the previous example and as a result the output of the trans-impedance amplifier saturates, resulting in pulse 102. As the amplifier has saturated, the output 102 will not follow the light pulse and drop after a duration T but will remain high for an indeterminate period before recovery 103. The recovery may well also lead to undershoot, 104, and ringing, 105. The recovery time may be very long in relation to the pulse duration, T.

Referring now to FIG. 2, an amplification arrangement for a DVD reading apparatus according to the present invention is shown schematically. An integrated optical detector for use in DVD readers comprises a

A photodiode 201 is positioned so as to detect a beam of light reflected from the surface of a spinning DVD. In response to the detection of incident light, the photodiode 201 generates a signal, which is input to a trans-impedance amplifier 203. In the example shown in FIG. 2, the photodiode 201 is connected between a positive supply rail (not shown) and a current mirror 202. In this manner, the current mirror 202 outputs to the trans-impedance amplifier 203 a current substantially identical to that flowing through the photodiode 201.

In alternative embodiments, it is of course possible that the output of the photodiode 201 may be connected directly to the input of the trans-impedance amplifier 203. In such embodiments, typically the photodiode 201 is connected between ground and the trans-impedance amplifier 203.

The output of the trans-impedance amplifier 203 is input to a voltage amplifier 204, to generate an output signal for processing. The trans-impedance amplifier 203 is provided with a feedback arrangement comprising a resister 205 in parallel with a capacitor 206 and a diode 207, in this case embodied by a transistor (such as an MOS transistor) arranged to act as a diode.

Referring now to FIG. 3, a plot of the output voltage of the trans-impedance amplifier 203 (Y-axis) against input voltage from the photodiode 203 (X-axis, proportional to detected light intensity) is shown. The solid line 301 shows the substantially linear response of the trans-impedance amplifier 203 up to its saturation voltage indicated by dashed line 303. Typically, the amplifier characteristics are such that the amplifier saturation voltage 303 is double the maximum expected normal operating voltage indicated by dashed line 302 in FIG. 3.

At an input voltage 304 wherein the corresponding output voltage 302 is equal to the maximum normal operating voltage 302, diode 207 begins to conduct and capacitor 206 becomes operative. As a result, the feedback conditions change, reducing the effective gain of the trans-impedance amplifier 203. This leads to the output voltage for a given input voltage following line 305 shown in FIG. 3. As the output voltage is increasing more slowly for a given increase in input voltage than in the normal operating range, a much larger input voltage can be tolerated without saturating the trans-impedance amplifier 203. In one preferred embodiment, the diode 207, capacitor 206, and resistor 205 are chosen such that the output voltage does not exceed the saturation level 303 unless the input voltage is ten times greater than that normally required to cause the output voltage to exceed the saturation level 303.

Curve 305 has a shallower slope and does not reach the saturation level 303 until the light amplitude is approximately ten times that of the normal maximum, 304.

The trans-impedance amplifier 203 is also provided with a diode clamp 208, operable to limit variations in the output voltage relative to a given reference voltage, thus improving the stability of the output voltage. The diode clamp comprises a diode connected between a reference voltage 209 and the amplifier 203. Such a diode 208 will limit output voltage of amplifier 203 in the event that the output value rises to a value close to the saturation level 303.

It is of course to be understood that the invention is not to be restricted to the details of the above embodiments which are described by way of example only.

1. An amplification arrangement, suitable for use in a DVD reading apparatus, comprising:
a trans-impedance amplifier adapted to receive an input signal and to provide an output signal;
a feedback resistor connected in parallel with the trans-impedance amplifier; and
a moderating arrangement connected in parallel with said feedback resistor and said trans-impedance amplifier wherein said moderating arrangement is operable to moderate the gain of the trans-impedance amplifier if the output signal of the trans-impedance amplifier exceeds a predetermined level.

2. An amplification arrangement as claimed in claim 1 wherein said moderating arrangement comprises a diode.

3. An amplification arrangement as claimed in claim 2 wherein the diode is adapted such when the output voltage of the trans-impedance amplifier is greater than a predetermined level, a current will flow through the diode.

4. An amplification arrangement as claimed in claim 2 wherein the diode is connected in parallel with additional feedback components.

5. An amplification arrangement as claimed in claim 4 wherein the additional feedback components comprise a capacitor arranged in parallel with a resistance.

6. An amplification arrangement as claimed in claim 2 wherein the diode is replaced with a transistor adapted to act as a diode.

7. An amplification arrangement as claimed in claim 1 wherein the amplification arrangement further incorporates a diode clamp operable to limit the magnitude of the output of the trans-impedance amplifier.

8. An amplification arrangement as claimed in claim 7 wherein said diode clamp comprises a diode connected between a reference voltage and the trans-impedance amplifier.

9. An amplification arrangement as claimed in any preceding claim wherein the amplification arrangement comprises a voltage amplifier connected to the output of the trans-impedance amplifier.

10. An amplification arrangement as claimed in claim 1 wherein the input signal is generated by a photodiode.

11. An amplification arrangement as claimed in claim 10 wherein a current mirror is provided between said photodiode and said amplification arrangement, one output of the current mirror being input into the trans-impedance amplifier.

12. An amplification arrangement as claimed in claim 11 wherein the photodiode is connected between a positive supply rail and the current mirror.

13. An amplification arrangement as claimed in claim 10 wherein the photodiode is connected to ground.

14. An amplification arrangement as claimed in 1 claim wherein the amplification arrangement is implemented in a CMOS integrated circuit or a BiCMOS integrated circuit.

15. An amplification arrangement as claimed in claim 14 wherein said photodiode is implemented as part of the same integrated circuit as said amplification arrangement.

16. An amplification arrangement as claimed in claim 14 wherein said current mirror is implemented as part of the same integrated circuit as said amplification arrangement.

17. A DVD reading apparatus comprising:
a plurality of photodiodes; a plurality of amplification arrangements, each amplification arrangement associated with one of the plurality of photodiodes; and
processing circuitry wherein the output of each photodiode is connected to an amplification arrangement and the output of each amplification arrangement is connected to the processing circuitry wherein each amplification arrangement is an amplification arrangement that includes:
a trans-impedance amplifier adapted to receive an input signal and to provide an output signal,
a feedback resistor connected in parallel with the trans-impedance amplifier; and
a moderating arrangement connected in parallel with said feedback resistor and said trans-impedance amplifier wherein said moderating arrangement is operable to moderate the gain of the trans-impedance amplifier if the output signal of the trans-impedance amplifier exceeds a predetermined level.

18. A DVD reading apparatus as claimed in claim 17 wherein the DVD reading apparatus additionally comprises means for generating and directing a beam of light at any desired point on the surface of a DVD.

19. A DVD reading apparatus as claimed in claim 18 wherein the plurality of photodiodes are mounted such that light reflected from said desired point on the DVD surface is incident upon the photodiodes.

20. A DVD reading apparatus as claimed in claim 18 wherein the means for generating light is adapted to generate light of a suitable wavelength or wavelength range.

21. A DVD reading apparatus as claimed in claim 19 wherein the photodiodes are adapted to detect only light of the same wavelength as that reflected from the DVD.

22. A DVD reading apparatus as claimed in claim 17 wherein the DVD reading apparatus additionally comprises means for retaining and rotating a DVD.

23. A DVD reading apparatus as claimed in claim 17 wherein the plurality of photodiodes comprises four or eight photodiodes.

24. A DVD reading apparatus as claimed in claim 17 wherein the outputs of the amplification arrangements associated with each photodiode are input to the processing circuitry individually.

25. A DVD reading apparatus as claimed in claim 17 wherein each said output of each amplification arrangement is additionally fed to separate inputs of a multi-input summing amplifier to generate a combined output signal.

26. A DVD reading apparatus as claimed in claim 25 wherein the combined output signal is used as a clock signal.
